(19) United States
(12) Patent Application Publication
(10) Pub. No.: US 2025/0301886 A1
(43) Pub. Date: Sep. 25, 2025

(54) DISPLAY DEVICE AND METHOD FOR FABRICATING THE SAME

(71) Applicant: Samsung Display Co., LTD., Yongin-si (KR)

(72) Inventors: Hyun Jin MAENG, Yongin-si (KR); Sang Chul BYUN, Yongin-si (KR)

(21) Appl. No.: 18/991,228

(22) Filed: Dec. 20, 2024

(30) Foreign Application Priority Data
Mar. 25, 2024 (KR) 10-2024-0040181

(51) Int. Cl. H10K 59/80; H10K 59/12

(52) U.S. Cl. CPC H10K 59/873; H10K 59/1201

(57) ABSTRACT

The present disclosure relates to a display device, and more particularly, to a display device and a method for fabricating the same in which an interfacial peeling phenomenon between a cover layer and a substrate may be reduced or minimized and a permeation path of external air and moisture may be blocked. A display device includes: a substrate; an intermediate layer on the substrate, and including a first electrode, a light emitting layer on the first electrode, a second electrode on the light emitting layer, and a filling layer on the second electrode; and a cover layer on the intermediate layer, wherein the cover layer is on a top surface of the intermediate layer, a side surface of the intermediate layer, and a side surface of the substrate.

### CROSS-REFERENCE TO RELATED APPLICATION

The present application claims priority to and the benefit of Korean Patent Application No. 10-2024-0040181, filed on Mar. 25, 2024, in the Korean Intellectual Property Office, the entire content of which is incorporated by reference herein.

### BACKGROUND

### 1. Field

The present disclosure relates to a display device, and more particularly, to a display device and a method for fabricating the same.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 pixels per inch (PPI) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is disposed on a semiconductor wafer substrate on which a complementary metal oxide semiconductor (CMOS) is disposed.

### SUMMARY

Aspects and features of embodiments of the present disclosure provide a display device and a method for fabricating the same in which an interfacial peeling phenomenon between a cover layer and a substrate may be reduced or minimized and a permeation path of external air and moisture may be blocked.

According to one or more embodiments of the present disclosure, a display device includes: a substrate; an intermediate layer on the substrate, and including a first electrode, a light emitting layer on the first electrode, a second electrode on the light emitting layer, and a filling layer on the second electrode; and a cover layer on the intermediate layer, wherein the cover layer is on a top surface of the intermediate layer, a side surface of the intermediate layer, and a side surface of the substrate.

In one or more embodiments, the cover layer is on the filling layer.

In one or more embodiments, the cover layer includes: a first sub-cover layer on the intermediate layer; and a second sub-cover layer extending from the first sub-cover layer and on the side surface of the intermediate layer and the side surface of the substrate.

In one or more embodiments, the first sub-cover layer is on the intermediate layer, and the second sub-cover layer is around the side surface of the intermediate layer and the side surface of the substrate.

In one or more embodiments, the second sub-cover layer has a diagonally inclined surface at one end.

In one or more embodiments, the inclined surface of the second sub-cover layer is on the side surface of the substrate.

In one or more embodiments, one end of the second sub-cover layer has a carbonized region.

In one or more embodiments, the cover layer is around the side surface of the intermediate layer and the side surface of the substrate.

In one or more embodiments, the intermediate layer is surrounded by the cover layer and the substrate.

In one or more embodiments, the substrate has a groove at an edge.

In one or more embodiments, in a plan view, the groove is around the intermediate layer.

In one or more embodiments, the groove has a triangular cross section.

In one or more embodiment, a part of the cover layer is in the groove.

In one or more embodiments, the groove includes a plurality of grooves, and respective lengths of the plurality of grooves increase as the grooves are positioned closer to the side surface of the substrate.

In one or more embodiment, a part of the cover layer is in each of the plurality of grooves.

In one or more embodiments, the display device further includes a polarizing plate on the intermediate layer.

According to one or more embodiments of the present disclosure, a display device includes: a substrate; an intermediate layer on the substrate; and a cover layer on the intermediate layer, wherein the intermediate layer includes a light emitting layer, and the cover layer is on a top surface of the intermediate layer, a side surface of the intermediate layer, and a side surface of the substrate.

In one or more embodiments, the cover layer is around the side surface of the intermediate layer and the side surface of the substrate.

In one or more embodiments, the intermediate layer is surrounded by the cover layer and the substrate.

In one or more embodiments, the substrate has a groove at an edge.

In one or more embodiments, in a plan view, the groove is around the intermediate layer.

In one or more embodiments, the groove has a triangular cross section.

In one or more embodiments, a part of the cover layer is in the groove.

According to one or more embodiments of the present disclosure, a method for fabricating a display device includes: forming an intermediate layer including a light emitting layer, on a base substrate; forming a groove at an edge of the base substrate; forming a cover layer which is inserted into the groove of the base substrate, and on a top surface of the intermediate layer and a side surface of the intermediate layer; and removing an edge portion of the base substrate based on the groove to form a substrate, wherein after the removing of the edge portion of the base substrate, the cover layer is formed on the top surface of the intermediate layer, the side surface of the intermediate layer, and a side surface of the substrate.

In one or more embodiments, the forming of the groove at the edge of the base substrate includes etching an edge of a top surface of the base substrate.

In one or more embodiments, the removing of the edge portion of the base substrate based on the groove to form the substrate includes irradiating a laser beam from below the base substrate toward the groove.

The display device and the method for fabricating the same according to one or more embodiments, it is possible to reduce or minimize the interfacial peeling phenomenon between the cover layer and the substrate, and block the permeation path of external air and moisture.

The effects, aspects, and features according to embodiments of the present disclosure are not limited to those mentioned above and more various effects, aspects, and features are included in the following description of the present disclosure.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is an exploded perspective view showing a display device according to one or more embodiments;

FIG. 2 is a layout diagram illustrating an example of the display panel shown in FIG. 1;

FIG. 3 is an equivalent circuit diagram of a first sub-pixel according to one or more embodiments;

FIG. 4 is a block diagram illustrating a display device according to one or more embodiments;

FIGS. 5 and 6 are layout diagrams illustrating pixels of a display area according to one or more embodiments;

FIG. 7 is a cross-sectional view of a display device according to one or more embodiments;

FIG. 8 is a perspective view of a display device according to one or more embodiments;

FIGS. 9-15 are process cross-sectional views illustrating a method of fabricating a display device according to one or more embodiments;

FIG. 16 is a cross-sectional view of a display device according to one or more embodiments;

FIGS. 17-23 are process cross-sectional views illustrating a method of fabricating a display device according to one or more embodiments;

FIG. 24 is a cross-sectional view of a display device according to one or more embodiments;

FIG. 25 is a perspective view illustrating a head mounted display according to one or more embodiments;

FIG. 26 is an exploded perspective view illustrating an example of the head mounted display of FIG. 25; and

FIG. 27 is a perspective view illustrating a head mounted display according to one or more embodiments.

### DETAILED DESCRIPTION

Hereinafter, embodiments of the present disclosure will be described with reference to the accompanying drawings.

In this specification, it will be understood that when an element (or a region, a layer, a portion, or the like) is referred to as being “on”, “connected to” or “coupled to” another element, it may be directly connected or coupled to the other element, or an intervening element may be disposed therebetween.

Like numerals or symbols refer to like elements throughout. Also, in the drawings, the thicknesses, ratios, and dimensions of the elements are exaggerated for effective description of the technical contents. The term “and/or” includes all of one or more combinations which the associated elements may define.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the spirit and scope of the present disclosure. The singular forms include the plural forms as well unless the context clearly indicates otherwise.

Also, terms such as “below”, “on lower side”, “above”, and “on upper side” are used to describe the relationships of the elements illustrated in the drawings. These terms have relative concepts and are described on the basis of the directions indicated in the drawings.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, and/or combinations thereof.

As used herein, “directly disposed” may mean that there is no layer, film, region, plate, etc. added between a portion such as a layer, film, region, or plate and another portion. For example, “directly disposed” may mean that two layers or two members are disposed without using an additional member such as an adhesive member therebetween.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized and/or overly formal sense unless expressly so defined herein.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, a display panel according to one or more embodiments of the present disclosure and a manufacturing method of a display panel will be described with reference to the accompanying drawings.

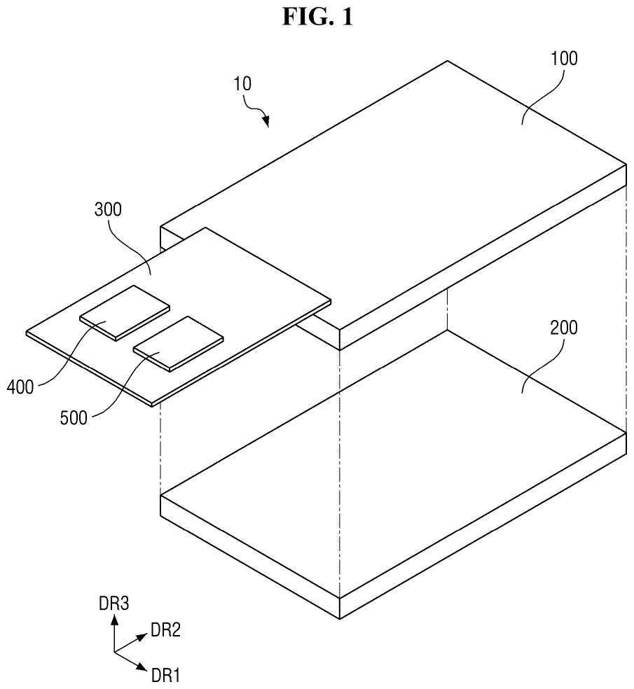

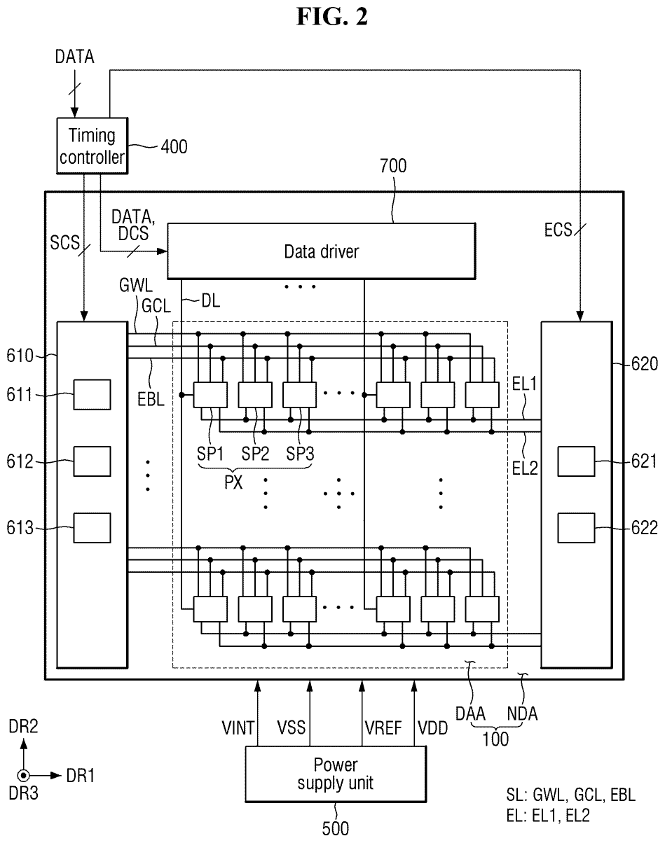

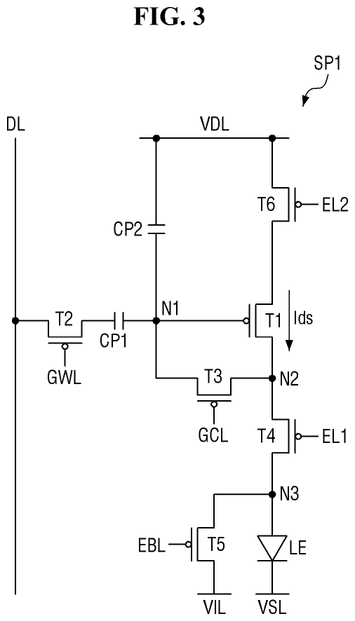

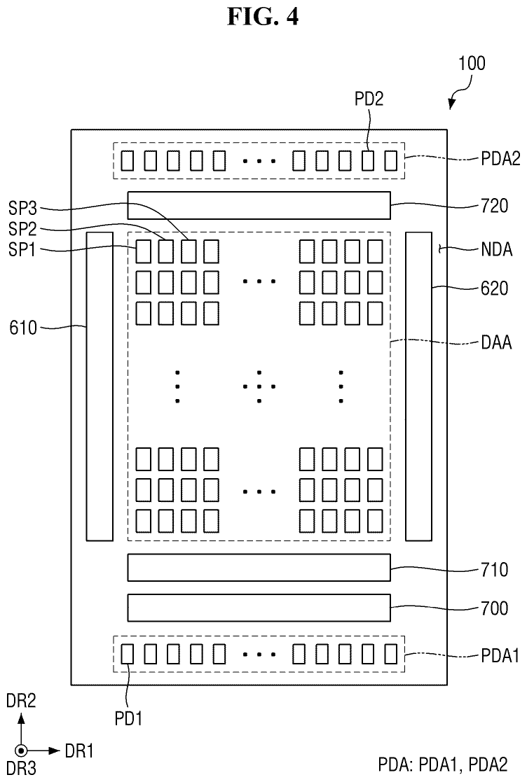

FIG. 1 is an exploded perspective view showing a display device according to one or more embodiments. FIG. 2 is a layout diagram illustrating an example of the display panel shown in FIG. 1. FIG. 3 is an equivalent circuit diagram of a first sub-pixel according to one or more embodiments. FIG. 4 is a block diagram illustrating a display device according to one or more embodiments.

Referring to FIGS. 1 and 2, a display device 10 according to one or more embodiments is a device for displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, and/or an Internet-of-Things (IoT) terminal. Alternatively, the display device 10 according to one or more embodiments may be applied to a smart watch, a watch phone, a head mounted display (HMD) for implementing virtual reality and/or augmented reality, and/or the like.

The display device 10 according to one or more embodiments includes a display panel 100, a heat dissipation layer 200, a circuit board 300, a driving circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a suitable curvature (e.g., a predetermined curvature). The planar shape of the display panel 100 is not limited to a quadrilateral shape, and may be a shape similar to another polygonal shape, a circular shape, and/or an elliptical shape. The planar shape of the display device 10 may conform to the planar shape of the display panel 100, but the present disclosure is not limited thereto.

The display panel 100 includes a display area DAA displaying an image and a non-display area NDA not displaying an image as shown in FIG. 2.

The display area DAA includes a plurality of pixels PX, a plurality of scan lines SL, a plurality of emission control lines EL, and a plurality of data lines DL.

Each of the plurality of pixels PX includes a light emitting element that emits light. The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being disposed along the second direction DR2. The plurality of data lines DL may extend in the second direction DR2, while being disposed along the first direction DR1.

The plurality of scan lines SL include a plurality of write scan lines GWL, a plurality of control scan lines GCL, and a plurality of bias scan lines EBL. The plurality of emission control lines EL include a plurality of first emission control lines EL1 and a plurality of second emission control lines EL2.

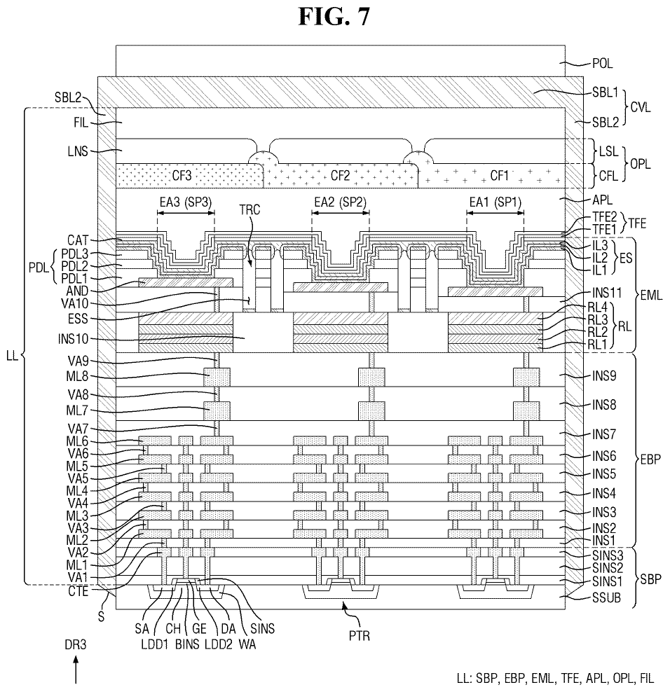

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors may be formed of complementary metal oxide semiconductor (CMOS).

Each of the plurality of sub-pixels SP1, SP2, and SP3 may be connected to one write scan line GWL from among the plurality of write scan lines GWL, one control scan line GCL from among the plurality of control scan lines GCL, one bias scan line EBL from among the plurality of bias scan lines EBL, one first emission control line EL1 from among the plurality of first emission control lines EL1, one second emission control line EL2 from among the plurality of second emission control lines EL2, and one data line DL from among the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

The non-display area NDA includes a scan driving area, a data driving area, and a pad area PDA.

The scan driving area SDA may be an area in which a scan driver 610 and an emission driver 620 are disposed. Although it is illustrated in FIG. 2 that the scan driver 610 is disposed on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from a timing control circuit (e.g., a timing controller) 410 of the driving circuit 400. The write scan signal output unit 611 may generate write scan signals according to the scan timing control signal SCS of the timing control circuit 410 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 410. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driving area may be an area in which a data driver 700 is disposed. The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 410. The data driver 700 converts the digital video data DATA into analog data voltages according to the data timing control signal DCS and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

The pad area PDA includes a plurality of pads PD arranged along the first direction DR1. Each of the plurality of pads PD may be exposed without being covered by a cover layer CVL (see FIG. 7) and a polarizing plate POL (see FIG. 7).

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), and/or aluminum (AI) having high thermal conductivity.

The circuit board 300 may be electrically connected to the plurality of pads PD in the pad area PDA of the display panel 100 by using a conductive adhesive member such as an anisotropic conductive film. The circuit board 300 may be a flexible printed circuit board (FPCB) with a flexible material, and/or a flexible film. Although the circuit board 300 is illustrated in FIG. 1 as being unfolded, the circuit board 300 may be bent. In this case, one end of the circuit board 300 may be disposed on the rear surface of the display panel 100. The one end of the circuit board 300 may be an end opposite to the other end of the circuit board 300 that is connected to the plurality of pads PD of the pad area PDA of the display panel 100 by using a conductive adhesive member.

The timing control circuit 410 may receive digital video data DATA and timing signals inputted from the outside. The timing control circuit 410 may generate the scan timing control signal SCS, the emission timing control signal ECS, and the data timing control signal DCS for controlling the display panel 100 in response to the timing signals. The timing control circuit 410 may output the scan timing control signal SCS to the scan driver 610, and output the emission timing control signal ECS to the emission driver 620. The timing control circuit 410 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, a reference voltage VREF, and a third driving voltage VINT and supply them to the display panel 100. Description of the first driving voltage VSS, the second driving voltage VDD, and the third driving voltage VINT will be provided later with reference to FIG. 4.

Each of the timing control circuit 410 of the driving circuit 400 and the power supply circuit 500 may be formed as an integrated circuit (IC) and attached to one surface of the circuit board 300. The scan timing control signal SCS, the emission timing control signal ECS, the digital video data DATA, and the data timing control signal DCS of the timing control circuit 410 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

Alternatively, the timing control circuit 410 may be disposed in a timing circuit area of the non-display area NDA of the display panel 100, similarly to the scan driver 610, the emission driver 620, and the data driver 700. In this case, the timing circuit area may be disposed between the data driving area and the pad area PDA.

FIG. 3 is an equivalent circuit diagram of a first sub-pixel according to one or more embodiments.

Referring to FIG. 3, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode (OLED) including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 includes a gate electrode connected to a first node N1, a source electrode connected to the drain electrode of the sixth transistor T6, and a drain electrode connected to a second node N2.

The second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

The third transistor T3 may be disposed between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode (e.g., the first transistor T1 may be diode-connected). The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 4 that the first sub-pixel SP1 includes six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 4. Therefore, the description of the equivalent circuit diagram of the second sub-pixel SP2 and the equivalent circuit diagram of the third sub-pixel SP3 is omitted in the present specification.

FIG. 4 is a block diagram illustrating a display device according to one or more embodiments. In FIG. 4, a layout diagram of the display panel 100 according to one or more embodiments is illustrated.

Referring to FIG. 4, the display area DAA of the display panel 100 according to one or more embodiments includes the plurality of pixels PX arranged in a matrix form. The non-display area NDA of the display panel 100 according to one or more embodiments include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. That is, the first pad portion PDA1 may be disposed closer to the edge of the display panel 100 than the data driver 700 is.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board (PCB) made of a rigid material or a flexible printed circuit board (FPCB) made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

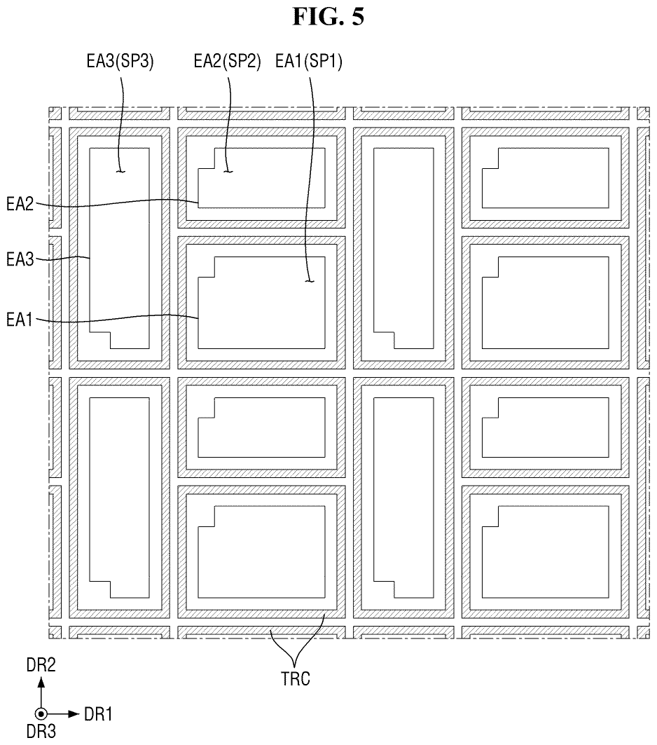

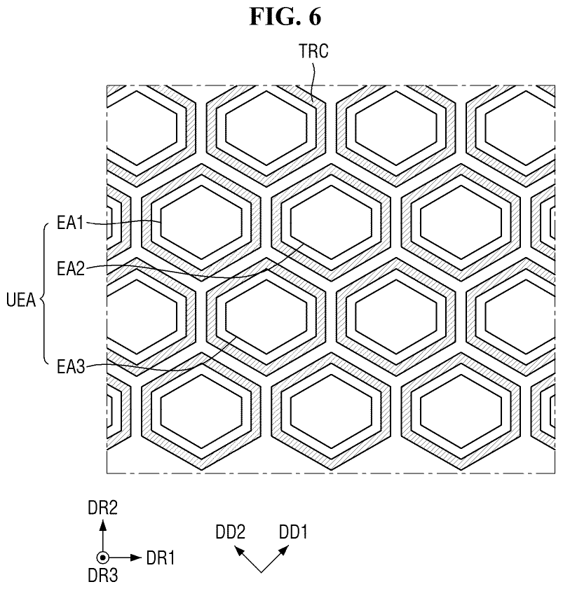

FIGS. 5 and 6 are layout diagrams illustrating pixels of a display area according to one or more embodiments.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have, in a plan view, a quadrilateral shape such as a rectangle, a square, and/or a diamond. For example, as shown in FIG. 5, the third emission area EA3 may have a rectangular shape, in a plan view, having a short side in the first direction DR1 and a long side in the second direction DR2. In addition, as shown in FIG. 5, each of the second emission area EA2 and the first emission area EA1 may have a rectangular shape, in a plan view, having a long side in the first direction DR1 and a short side in the second direction DR2.

The length of the third emission area EA3 in the first direction DR1 may be smaller than the length of the second emission area EA2 in the first direction DR1, and may be smaller than the length of the first emission area EA1 in the first direction DR1. The length of the second emission area EA2 in the first direction DR1 and the length of the first emission area EA1 in the first direction DR1 may be substantially the same.

The length of the third emission area EA3 in the second direction DR2 may be greater than the sum of the length of the second emission area EA2 in the second direction DR2 and the length of the first emission area EA1 in the second direction DR2. The length of the second emission area EA2 in the second direction DR2 may be less than the length of the first emission area EA1 in the second direction DR2.

Although it is illustrated in FIG. 5 that each of the first emission area EA1, the second emission area EA2, and the third emission area EA3 has a rectangular shape in a plan view, the present disclosure is not limited thereto. For example, each of the first emission area EA1, the second emission area EA2, and the third emission area EA3 may have a polygonal shape other than a quadrilateral shape, a circular shape, and/or an elliptical shape in a plan view.

In each of the plurality of pixels PX, the third emission area EA3 and the second emission area EA2 may be adjacent to each other in the first direction DR1. Further, the first emission area EA1 and the third emission area EA3 may be adjacent to each other in the first direction DR1. In addition, the second emission area EA2 and the first emission area EA1 may be adjacent to each other in the second direction DR2. The area of the first emission area EA1, the area of the second emission area EA2, and the area of the third emission area EA3 may be different.

Alternatively, as shown in FIG. 6, the first emission area EA1, the second emission area EA2, and the third emission area EA3 may have a hexagonal shape in a plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is shown as an example in FIG. 5 that each of the plurality of pixels PX includes three emission areas EA1, EA2, and EA3, but the present disclosure is not limited thereto. That is, each of the plurality of pixels PX may include four emission areas.

In addition, the disposition of the emission areas of the plurality of pixels PX is not limited to that illustrated in FIG. 5. For example, the emission areas of the plurality of pixels PX may be disposed in a stripe structure in which the emission areas are arranged along the first direction DR1, a PENTILE© structure in which the emission areas are arranged in a diamond shape, or a hexagonal structure in which the emission areas having, in a plan view, a hexagonal shape are arranged side by side as shown in FIG. 6. The PENTILE© pixel arrangement structure may be referred to as an RGBG matrix structure (e.g., a PENTILE© matrix structure or an RGBG structure (e.g., a PENTILE© structure)). PENTILE© is a registered trademark of Samsung Display Co., Ltd., Republic of Korea.

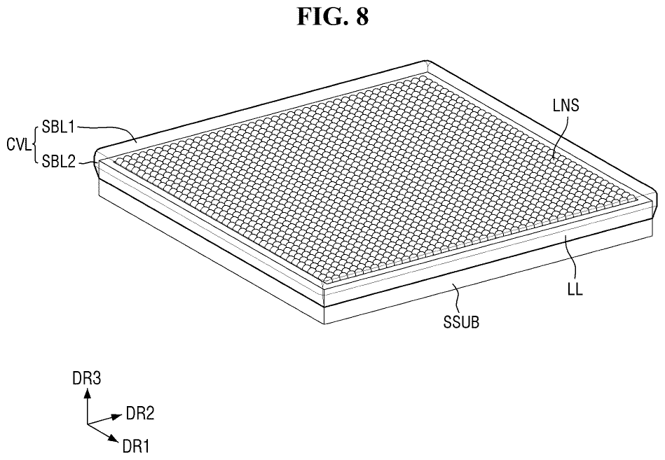

FIG. 7 is a cross-sectional view of a display device according to one or more embodiments, and FIG. 8 is a perspective view of a display device according to one or more embodiments. For example, FIG. 8 may be a perspective view of a display device including the semiconductor substrate SSUB, an intermediate layer LL, and the cover layer CVL of FIG. 7.

Referring to FIG. 7, the display panel 100 includes a semiconductor backplane SBP, a light emitting element backplane EBP, a display element layer EML, an encapsulation layer TFE, an organic layer APL, an optical layer OPL, a filling layer FIL, the cover layer CVL, and the polarizing plate POL.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, and/or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented.

A first semiconductor insulating layer SINS1 may be disposed on the semiconductor substrate SSUB covering the pixel transistor PTR. The first semiconductor insulating layer SINS1 may be formed of silicon carbonitride (SiCN) and/or a silicon oxide (SiOx)-based inorganic layer, but the present disclosure is not limited thereto.

A second semiconductor insulating layer SINS2 may be disposed on the first semiconductor insulating layer SINS1. The second semiconductor insulating layer SINS2 may be formed of a silicon oxide (SiOx)-based inorganic layer, but the present disclosure is not limited thereto.

The plurality of contact terminals CTE may be disposed on the second semiconductor insulating layer SINS2. Each of the plurality of contact terminals CTE may be connected to one of the gate electrode GE, the source region SA, or the drain region DA of each of the pixel transistors PTR through holes penetrating the first semiconductor insulating layer SINS1 and the second semiconductor insulating layer SINS2. The plurality of contact terminals CTE may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them.

A third semiconductor insulating layer SINS3 may be disposed on a side surface of each of the plurality of contact terminals CTE on the second semiconductor insulating layer SINS2. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the present disclosure is not limited thereto.

The semiconductor substrate SSUB may be replaced with a glass substrate and/or a polymer resin substrate such as polyimide. In this case, thin film transistors may be disposed on the glass substrate and/or the polymer resin substrate. The glass substrate may be a rigid substrate that does not bend, and the polymer resin substrate may be a flexible substrate that can be bent and/or curved.

The light emitting element backplane EBP includes a plurality of conductive layers ML1 to ML8, a plurality of vias VA1 to VA9, and a plurality of insulating layers INS1 to INS9. The light emitting element backplane EBP includes a plurality of insulating layers INS1 to INS9 disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first sub pixel SP1 shown in FIG. 3. For example, the first to sixth transistors T1 to T6 are merely formed on the semiconductor backplane SBP, and the connection of the first to sixth transistors T1 to T6 and the first and second capacitors CP1 and CP2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light emitting element LE is also accomplished through the first to eighth conductive layers ML1 to ML8.

A first insulating layer INS1 may be disposed on the semiconductor backplane SBP. Each of first vias VA1 may penetrate the first insulating layer INS1 to be connected to the contact terminal CTE exposed from the semiconductor backplane SBP. Each of first conductive layers ML1 may be disposed on the first insulating layer INS1 and may be connected to the first via VA1.

A second insulating layer INS2 may be disposed on the first insulating layer INS1 and the first conductive layers ML1. Each of second vias VA2 may penetrate the second insulating layer INS2 and may be connected to the exposed first conductive layer ML1. Each of second conductive layers ML2 may be disposed on the second insulating layer INS2 and may be connected to the second via VA2.

A third insulating layer INS3 may be disposed on the second insulating layer INS2 and the second conductive layers ML2. Each of third vias VA3 may penetrate the third insulating layer INS3 and may be connected to the exposed second conductive layer ML2. Each of third conductive layers ML3 may be disposed on the third insulating layer INS3 and may be connected to the third via VA3.

A fourth insulating layer INS4 may be disposed on the third insulating layer INS3 and the third conductive layers ML3. Each of fourth vias VA4 may penetrate the fourth insulating layer INS4 and may be connected to the exposed third conductive layer ML3. Each of fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of fifth vias VA5 may penetrate the fifth insulating layer INS5 and may be connected to the exposed fourth conductive layer ML4. Each of fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of sixth vias VA6 may penetrate the sixth insulating layer INS6 and may be connected to the exposed fifth conductive layer ML5. Each of sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of seventh vias VA7 may penetrate the seventh insulating layer INS7 and may be connected to the exposed sixth conductive layer ML6. Each of seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of eighth vias VA8 may penetrate the eighth insulating layer INS8 and may be connected to the exposed seventh conductive layer ML7. Each of eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The first to eighth vias VA1 to VA8 may be made of substantially the same material. First to eighth insulating layers INS1 to INS8 may be formed of a silicon oxide (SiOx)-based inorganic layer, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å; the thickness of each of the second conductive layer ML2, the third conductive layer ML3, the fourth conductive layer ML4, the fifth conductive layer ML5, and the sixth conductive layer ML6 may be approximately 1440 Å; and the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating layer INS9 may be disposed on the eighth insulating layer INS8 and the eighth conductive layer ML8. The ninth insulating layer INS9 may be formed of a silicon oxide (SiOx)-based inorganic layer, but the present disclosure is not limited thereto.

Each of ninth vias VA9 may penetrate the ninth insulating layer INS9 and may be connected to the exposed eighth conductive layer ML8. The ninth vias VA9 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. The thickness of the ninth via VA9 may be approximately 16500 Å.

The display element layer EML may be disposed on the light emitting element backplane EBP. The display element layer EML may include the light emitting elements LE each including a reflective electrode layer RL, tenth and eleventh insulating layers INS10 and INS11, a tenth via VA10, a first electrode AND, a light emitting stack ES, and a second electrode CAT; a pixel defining film PDL; and a plurality of trenches TRC.

The reflective electrode layer RL may be disposed on the ninth insulating layer INS9. The reflective electrode layer RL may include at least one reflective electrode RL1, RL2, RL3, and/or RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating layer INS9, and may be connected to the ninth via VA9. The first reflective electrodes RL1 may be formed of copper (Cu), aluminum (AI), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may include titanium nitride (TiN).

Each of the second reflective electrodes RL2 may be disposed on the first reflective electrode RL1. The second reflective electrodes RL2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

Each of the third reflective electrodes RL3 may be disposed on the second reflective electrode RL2. The third reflective electrodes RL3 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include titanium (Ti).

Because the second reflective electrode RL2 is an electrode that substantially reflects light from the light emitting elements LE, in one or more embodiments, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å. However, in one or more embodiments, the thickness of the second reflective electrode RL2 may be greater than the thickness of each of the first reflective electrode RL1, the third reflective electrode RL3, and the fourth reflective electrode RL4.

The tenth insulating layer INS10 may be disposed on the ninth insulating layer INS9. The tenth insulating layer INS10 may be disposed between the reflective electrode layers RL adjacent to each other in a horizontal direction (e.g., the first direction DR1 or the second direction DR2). In one or more embodiments, the tenth insulating layer INS10 may be disposed on the reflective electrode layer RL in the third pixel PX3. The tenth insulating layer INS10 may be formed of a silicon oxide (SiOx)-based inorganic layer, but the present disclosure is not limited thereto.

The eleventh insulating layer INS11 may be disposed on the tenth insulating layer INS10 and the reflective electrode layer RL. The eleventh insulating layer INS11 may be formed of a silicon oxide (SiOx)-based inorganic layer, but the present disclosure is not limited thereto. The tenth insulating layer INS10 and the eleventh insulating layer INS11 may be an optical auxiliary layer through which light reflected by the reflective electrode layer RL passes, from among light emitted from the light emitting elements LE.

In order to match the resonance distance of the light emitted from the light emitting elements LE in at least one of the first pixel PX1, the second pixel PX2, or the third pixel PX3, the tenth insulating layer INS10 and the eleventh insulating layer INS11 may not be disposed under the first electrode AND of the first pixel PX1. In one or more embodiments, the first electrode AND of the first pixel PX1 may be directly disposed on the reflective electrode layer RL. The eleventh insulating layer INS11 may be disposed under the first electrode AND of the first pixel PX1, the first electrode AND of the second pixel PX2, and the first electrode AND of the third pixel PX3, as shown in FIG. 7. In one or more embodiments, the tenth insulating layer INS10 and the eleventh insulating layer INS11 may be disposed under the first electrode AND of the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the tenth insulating layer INS10 and the eleventh insulating layer INS11 may be set in each of the first pixel PX1, the second pixel PX2, and the third pixel PX3. Further, the thickness of the eleventh insulating layer INS11 may be different in each of the first pixel PX1, the second pixel PX2, and the third pixel PX3 to adjust the distance from the reflective electrode layer RL to the second electrode CAT according to the main wavelength of the light emitted from each of the first pixel PX1, the second pixel PX2, and the third pixel PX3. For example, it is illustrated in FIG. 7 that the distance between the first electrode AND and the reflective electrode layer RL in the third pixel PX3 is greater than the distance between the first electrode AND and the reflective electrode layer RL in the second pixel PX2 and the distance between the first electrode AND and the reflective electrode layer RL in the first pixel PX1, and the distance between the first electrode AND and the reflective electrode layer RL in the second pixel PX2 is greater than the distance between the first electrode AND and the reflective electrode layer RL in the first pixel PX1, but the present disclosure is not limited thereto.

In addition, although the tenth insulating layer INS10 and the eleventh insulating layer INS11 are illustrated in the present disclosure, a twelfth insulating layer disposed under the first electrode AND of the first pixel PX1 may be added. In this case, the eleventh insulating layer INS11 and a twelfth insulating layer INS12 may be disposed under the first electrode AND of the second pixel PX2, and the tenth insulating layer INS10, the eleventh insulating layer INS11, and the twelfth insulating layer INS12 may be disposed under the first electrode AND of the third pixel PX3.

Each of the tenth vias VA10 may penetrate the tenth insulating layer INS10 and/or the eleventh insulating layer INS11 in the first pixel PX1, the second pixel PX2, and the third pixel PX3 and may be connected between the first electrode AND and the reflective electrode layer RL of the first pixel PX1, the second pixel PX2, and the third pixel PX3. The tenth vias VA10 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the tenth via VA10 in the second pixel PX2 may be smaller than the thickness of the tenth via VA10 in the third pixel PX3, and the thickness of the tenth via VA10 in the first pixel PX1 may be smaller than the thickness of the tenth via VA10 in the second pixel PX2.

The first electrode AND of each of the light emitting elements LE may be disposed on the eleventh insulating layer INS11 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first pixel PX1 to emit light. The second emission area EA2 may be defined as an area in which the first electrode AND, the light emitting stack ES, and the second electrode CAT are sequentially stacked in the second pixel PX2 to emit light. The third emission area EA3 may be defined as an area in which the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic layer, but the present disclosure is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic layer TFE1 from being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating layer INS11. In one or more embodiments, the tenth insulating layer INS10 may be partially recessed at each of the plurality of trenches TRC.

At least one trench TRC may be disposed between adjacent pixels PX1, PX2, and PX3. Although FIG. 7 illustrates that two trenches TRC are disposed between adjacent pixels PX1, PX2, and PX3, the present disclosure is not limited thereto.

The light emitting stack ES may include a plurality of stack layers. FIG. 7 illustrates that the light emitting stack ES has a three-tandem structure including a first stack layer IL1, a second stack layer IL2, and a third stack layer IL3, but the present disclosure is not limited thereto. For example, the light emitting stack ES may have a two-tandem structure including two sub-layers.

In the three-tandem structure, the light emitting stack ES may have a tandem structure including a plurality of stack layers IL1, IL2, and IL3 that emit different lights. For example, the light emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be separated between adjacent pixels PX1, PX2, and PX3. The second stack layer IL2 may be disposed on the first stack layer IL1. Due to the trench TRC, the second stack layer IL2 may be separated between adjacent pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure for cutting off the first and second stack layers IL1 and IL2, the first charge generation layer, and the second charge generation layer of the display element layer EML between the pixels PX1, PX2, and PX3 adjacent to each other. In addition, in the two-tandem structure, each of the trenches TRC may be a structure for cutting off the charge generation layer disposed between a lower sub-layer and an upper sub-layer, and the lower sub-layer.

In order to stably cut off the first and second stack layers IL1 and IL2 of the display element layer EML between adjacent pixels PX1, PX2, and PX3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be disposed on the pixel defining film PDL.

The number of the stack layers IL1, IL2, and IL3 that emit different lights is not limited to that shown in FIG. 7. For example, the light emitting stack ES may include two sub-layers. In this case, one of the two sub-layers may be substantially the same as the first stack layer IL1, and the other may include a second hole transport layer, a second organic light emitting layer, a third organic light emitting layer, and a second electron transport layer. In this case, a charge generation layer for supplying electrons to one sub-layer and supplying charges to the other sub-layer may be disposed between the two sub-layers.

In addition, FIG. 7 illustrates that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO and/or IZO that can transmit light or a semi-transmissive conductive material such as magnesium (Mg), silver (Ag), and/or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic layer TFE1 and TFE2 to prevent oxygen and/or moisture from permeating into the display element layer EML. For example, the encapsulation layer TFE may include the first encapsulation inorganic layer TFE1, and a second encapsulation inorganic layer TFE2.

The first encapsulation inorganic layer TFE1 may be disposed on the second electrode CAT. The first encapsulation inorganic layer TFE1 may be formed as a multilayer in which one or more inorganic layers selected from silicon nitride (SiNx), silicon oxy nitride (SiON), and/or silicon oxide (SiOx) are alternately stacked. The first encapsulation inorganic layer TFE1 may be formed by a chemical vapor deposition (CVD) process.

The second encapsulation inorganic layer TFE2 may be disposed on the first encapsulation inorganic layer TFE1. The second encapsulation inorganic layer TFE2 may be formed of titanium oxide (TiOx) and/or aluminum oxide (AIOx), but the present disclosure is not limited thereto. The second encapsulation inorganic layer TFE2 may be formed by an atomic layer deposition (ALD) process. The thickness of the second encapsulation inorganic layer TFE2 may be smaller than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, and/or polyimide resin.

The optical layer OPL may include a color filter layer CFL and a lens layer LSL.

The color filter layer CFL may include the first to third color filters CF1, CF2, and CF3. The first to third color filters CF1, CF2, and CF3 may be disposed on the organic layer APL.

The first color filter CF1 may overlap the first emission area EA1 of the first pixel PX1. The first color filter CF1 may transmit light of the first color, i.e., light of a blue wavelength band. The blue wavelength band may be approximately 370 nm to 460 nm. Thus, the first color filter CF1 may transmit light of the first color from among light emitted from the first emission area EA1.

The second color filter CF2 may overlap the second emission area EA2 of the second pixel PX2. The second color filter CF2 may transmit light of the second color, i.e., light of a green wavelength band. The green wavelength band may be approximately 480 nm to 560 nm. Thus, the second color filter CF2 may transmit light of the second color from among light emitted from the second emission area EA2.

The third color filter CF3 may overlap the third emission area EA3 of the third pixel PX3. The third color filter CF3 may transmit light of the third color, i.e., light of a red wavelength band. The red wavelength band may be approximately 600 nm to 750 nm. Thus, the third color filter CF3 may transmit light of the third color from among light emitted from the third emission area EA3.

The lens layer LSL may include a plurality of lenses LNS. The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction (e.g., the third direction DR3).

The filling layer FIL may be disposed on the optical layer OPL. For example, the filling layer FIL may be disposed on the lens layer LSL. In other words, the filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, and/or polyimide resin.

The cover layer CVL may be disposed on the filling layer FIL. In addition, the cover layer CVL may be disposed on the side surface of the substrate (e.g., the semiconductor substrate SSUB) and the side surface of the intermediate layer LL (e.g., LL: SBP, EBP, EML, TFE, APL, OPL, FIL). For example, as shown in FIGS. 7 and 8, the cover layer CVL may be disposed on the side surface of the semiconductor substrate SSUB and the side surface of the intermediate layer LL to be around (e.g., to surround) the side surface of the semiconductor substrate SSUB and the side surface of the intermediate layer LL. The cover layer CVL may be a glass substrate and/or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

According to one or more embodiments, the cover layer CVL may include a first sub-cover layer SBL1 and a second sub-cover layer SBL2. The first sub-cover layer SBL1 and the second sub-cover layer SBL2 may be formed as one body.

The first sub-cover layer SBL1 may be disposed on the filling layer FIL. For example, the first sub-cover layer SBL1 may be disposed on the entire surface of the filling layer FIL to overlap all components disposed below the filling layer FIL. The first sub-cover layer SBL1 may be in contact with the filling layer FIL.

The second sub-cover layer SBL2 may extend from the first sub-cover layer SBL1. For example, the second sub-cover layer SBL2 may extend from the side surface of the first sub-cover layer SBL1 in the reverse direction of the third direction DR3 (hereinafter, referred to as a third reverse direction). In other words, the second sub-cover layer SBL2 may extend in a direction perpendicular to the extension direction of the first sub-cover layer SBL1. The second sub-cover layer SBL2 may be disposed on the side surface of the substrate (e.g., the semiconductor substrate SSUB) and the side surface of the intermediate layer LL. According to one or more embodiments, the second sub-cover layer SBL2 may have a diagonally inclined surface S. For example, the second sub-cover layer SBL2 may have the inclined surface S at one end, and the inclined surface S may be disposed on the side surface of the semiconductor substrate SSUB. The inclined surface S may allow the second sub-cover layer SBL2 to have an angle smaller than 90 degrees at the portion overlapping the side surface of the semiconductor substrate SSUB. For example, at one end of the second sub-cover layer SBL2 that overlaps the side surface of the semiconductor substrate SSUB, the interior angle of the second sub-cover layer SBL2 may be an acute angle. According to one or more embodiments, at least a part of the inclined surface S of the second sub-cover layer SBL2 may have a carbonized region.

The intermediate layer LL may include a layer disposed between the semiconductor substrate SSUB and the cover layer CVL. For example, the intermediate layer LL may include the first semiconductor insulating layer SINS1, the second semiconductor insulating layer SINS2, the third semiconductor insulating layer SINS3, the lower insulating layer BINS, the side insulating layer SINS, the gate electrode GE, the plurality of contact terminals CTE, the light emitting element backplane EBP, the display element layer EML, the encapsulation layer TFE, the organic layer APL, the optical layer OPL, and the filling layer FIL described above.

The intermediate layer LL may be surrounded by the aforementioned cover layer CVL and the substrate (e.g., semiconductor substrate SSUB). In other words, the cover layer CVL and the substrate may be around (e.g., may surround) all surfaces of the intermediate layer LL. For example, the cover layer CVL may be disposed on the top and side surfaces of the intermediate layer LL, and the semiconductor substrate SSUB may be disposed on the bottom surface of the intermediate layer LL, so that the cover layer CVL and the semiconductor substrate SSUB may be around (e.g., may surround) all surfaces of the intermediate layer LL.

According to one or more embodiments, because the cover layer CVL is formed not only on the top surface of the intermediate layer LL but also on the side surface of the intermediate layer LL and the side surface of the semiconductor substrate SSUB, the bonding area of the cover layer CVL may be increased. Accordingly, it is possible to reduce or minimize the interfacial peeling phenomenon between the cover layer CVL and the structure bonded thereto (e.g., the intermediate layer LL and the semiconductor substrate SSUB). In addition, because the cover layer CVL extends to the side surface of the semiconductor substrate SSUB, the permeation path of external air and moisture into the intermediate layer LL and the semiconductor substrate SSUB may be blocked.

The polarizing plate POL may be disposed on one surface of the cover layer CVL. For example, the polarizing plate may be disposed on the first sub-cover layer SBL1 of the cover layer CVL. Accordingly, the first sub-cover layer SBL1 may be disposed between the aforementioned filling layer FIL and the polarizing plate POL. The polarizing plate POL may be a structure for preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

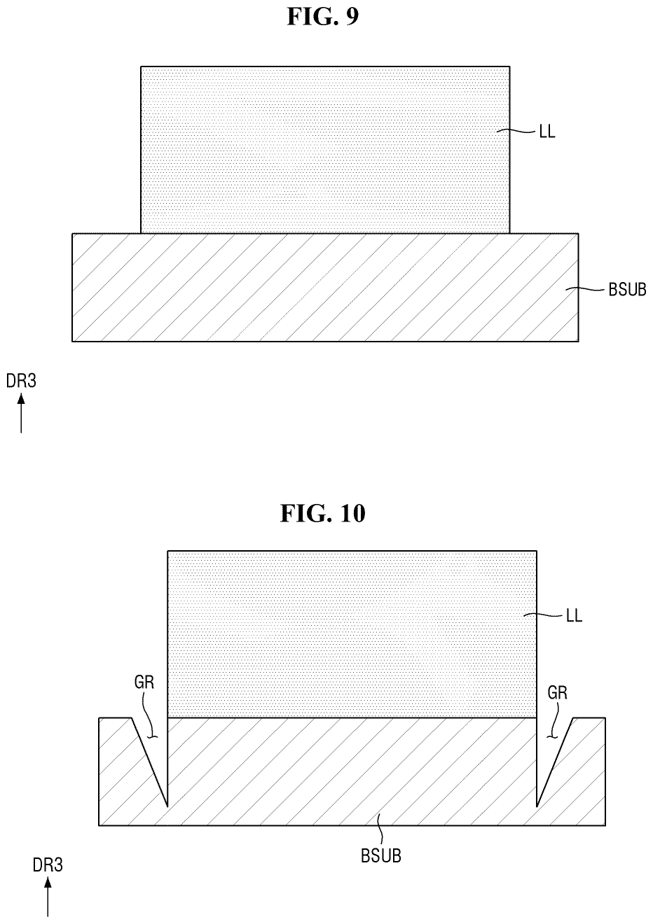

FIGS. 9-15 are process cross-sectional views illustrating a method for fabricating a display device according to one or more embodiments. For example, FIGS. 9-15 may be process cross-sectional views for describing the method for fabricating the aforementioned display device of FIG. 7.

First, as shown in FIG. 9, the intermediate layer LL may be disposed on a mother substrate including a base substrate BSUB (e.g., the semiconductor substrate SSUB). Here, as described above, the base substrate BSUB may include the well region WA, the source region SA, the drain region DA, the channel region CH, the first low-concentration impurity region LDD1, and the second low-concentration impurity region LDD2. According to one or more embodiments, the aforementioned mother substrate may include a wafer.

The intermediate layer LL may include the first semiconductor insulating layer SINS1, the second semiconductor insulating layer SINS2, the third semiconductor insulating layer SINS3, the lower insulating layer BINS, the side insulating layer SINS, the gate electrode GE, the plurality of contact terminals CTE, the light emitting element backplane EBP, the display element layer EML, the encapsulation layer TFE, the organic layer APL, the optical layer OPL, and the filling layer FIL described above.

Subsequently, as shown in FIG. 10, a groove GR may be formed at the edge of the base substrate BSUB. The groove GR may be formed in the base substrate BSUB in a recessed shape in the third reverse direction. The groove GR may have a triangular cross section as illustrated in FIG. 10. For example, the groove GR may have a triangular cross section having a width that gradually decreases along the third reverse direction. According to one or more embodiments, the groove GR may have a closed curve shape around (e.g., surrounding) the intermediate layer LL in a plan view. For example, the groove GR may have a quadrangular ring shape around (e.g., surrounding) the intermediate layer LL in a plan view.

The groove GR may be formed by removing a part of the base substrate BSUB. For example, the groove GR may be formed through an etching process on the base substrate BSUB. For example, the aforementioned groove GR may be formed by selectively etching the edge of the base substrate BSUB using an etchant and/or an etching gas.

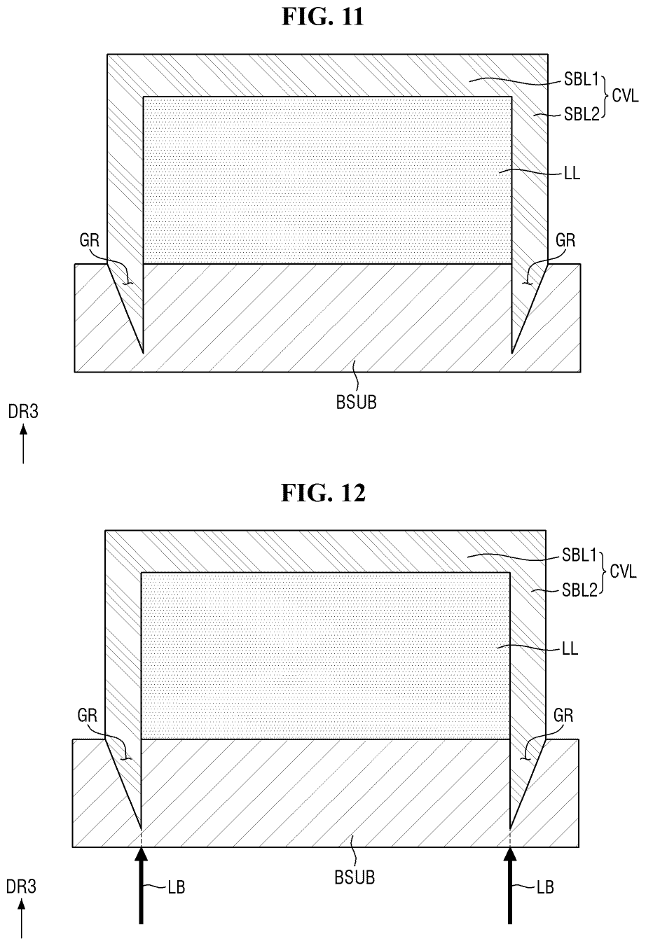

Thereafter, as shown in FIG. 11, the cover layer CVL may be formed on the intermediate layer LL and the base substrate BSUB. In this case, the cover layer CVL may be disposed on the top surface of the intermediate layer LL and the side surface of the intermediate layer LL. In addition, a part of the cover layer CVL may be disposed in the groove GR of the base substrate BSUB. For example, the first sub-cover layer SBL1 of the cover layer CVL may be disposed on the intermediate layer LL, the second sub-cover layer SBL2 of the cover layer CVL may be disposed on the side surface of the intermediate layer LL, and a part of the second sub-cover layer SBL2 of the cover layer CVL may be disposed in the groove GR of the base substrate BSUB. According to one or more embodiments, the part of the second sub-cover layer SBL2 may have the same cross-sectional shape as the groove GR. For example, the part of the second sub-cover layer SBL2 disposed in the groove GR may have a triangular cross-sectional shape.

According to one or more embodiments, the cover layer CVL may be patterned through a patterning process to be disposed on the top surface of the intermediate layer LL and the side surface of the intermediate layer LL, and in the groove GR of the base substrate BSUB as illustrated in FIG. 11. The aforementioned patterning process may include, for example, a photolithography process and/or an etching process. As a specific example, a polymer resin may be applied (or coated) on the filling layer FIL of the intermediate layer LL and the base substrate BSUB to form a polymer resin layer, and the polymer resin layer may be patterned through a photolithography process and/or an etching process as described above, thereby forming the cover layer CVL.

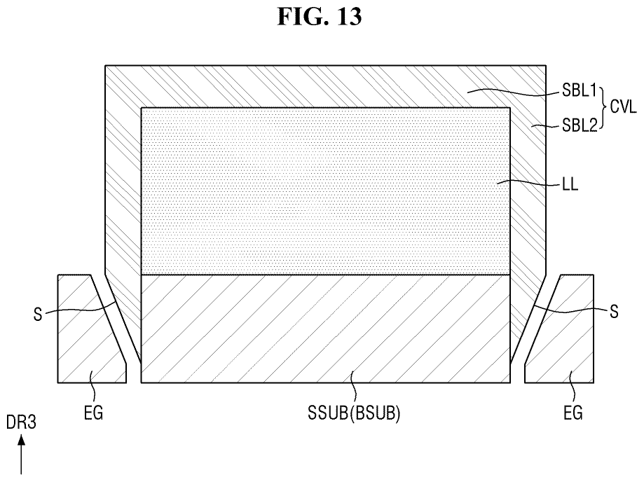

Subsequently, as shown in FIGS. 12 and 13, a process of removing a part of the base substrate BSUB may be performed. For example, the process of removing a part of the base substrate BSUB may include a scribing process of cutting the base substrate BSUB into cells (or wafer chips).

The aforementioned cutting process of the base substrate BSUB may be performed, for example, by a laser cutting process. For example, as shown in FIG. 12, a laser beam LB may be irradiated from below the base substrate BSUB toward the groove GR of the base substrate BSUB in the third direction DR3. According to one or more embodiments, the laser beam LB may be irradiated toward the vertex of the triangular groove GR. For example, the laser beam LB may be irradiated toward a portion of the groove GR (e.g., the vertex of the groove GR) located at the lowest portion of the base substrate BSUB. Then, the laser beam LB may penetrate the base substrate BSUB and reach the vertex of the groove GR. In this case, the laser beam LB may be irradiated to the cover layer CVL (e.g., the end of the second sub-cover layer SBL2) disposed in the groove GR. Accordingly, the end of the second sub-cover layer SBL2 may be at least partially carbonized. The carbonized region may have a black color, for example.

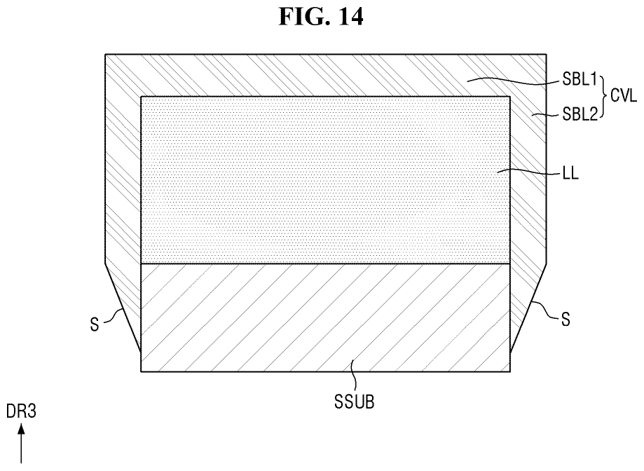

When the aforementioned laser cutting process is completed, both edge portions of the base substrate BSUB may be removed as shown in FIG. 13. For example, an edge portion EG of the base substrate BSUB disposed on the outside of the region, to which the laser beam LB is irradiated, may be removed. In this case, because an adhesive force between the inclined surface S of the cover layer CVL and the inclined surface of the edge portion EG facing the inclined surface S is small, when the portion of the base substrate BSUB corresponding to the vertex of the groove GR described above is removed by irradiation of the laser beam LB, the edge portion EG of the base substrate BSUB may be easily removed from the main body of the base substrate BSUB. Therefore, the edge portion EG of the base substrate BSUB is removed by the laser cutting process of FIGS. 12 and 13, thereby forming a substrate of a single cell unit (e.g., the semiconductor substrate SSUB). Then, as shown in FIG. 14, the cover layer CVL disposed on the top surface of the intermediate layer LL, the side surface of the intermediate layer LL, and the side surface of the semiconductor substrate SSUB may be formed.

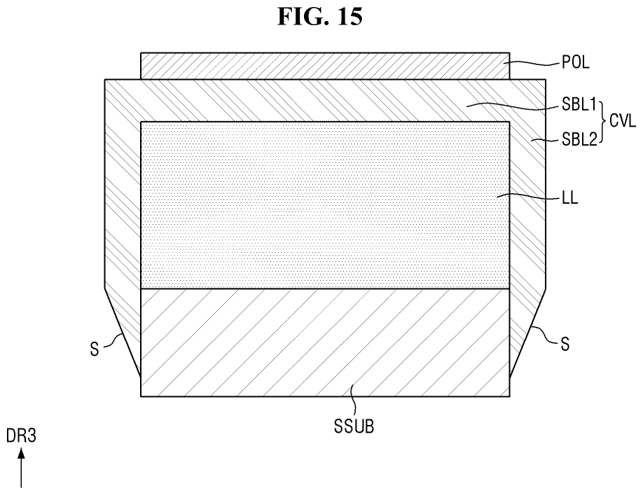

Thereafter, as shown in FIG. 15, the polarizing plate POL may be disposed on the top surface of the cover layer CVL, above the intermediate layer LL. For example, the polarizing plate POL may be disposed on the first sub-cover layer SBL1 of the cover layer CVL.

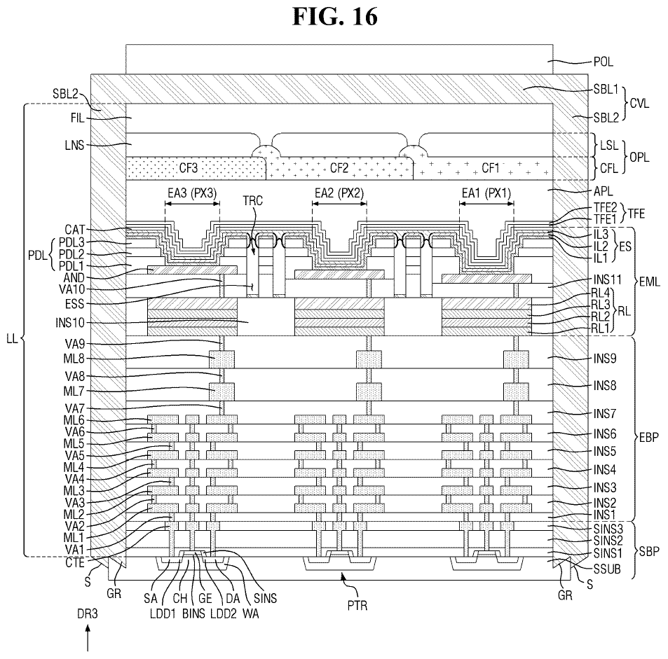

FIG. 16 is a cross-sectional view of a display device according to one or more embodiments.

The display device of FIG. 16 is different from the aforementioned display device of FIG. 7 in the shape of the substrate (e.g., the semiconductor substrate SSUB) and the shape of the cover layer CVL. The following description will be directed to the difference.

The semiconductor substrate SSUB may have at least one groove GR. For example, as shown in FIG. 16, the groove GR may be formed at the edge of the semiconductor substrate SSUB. The groove GR may be formed in the semiconductor substrate SSUB in a recessed shape in the third reverse direction. The groove GR may have a triangular cross section as illustrated in FIG. 16. For example, the groove GR may have a triangular cross section having a width that gradually decreases along the third reverse direction. According to one or more embodiments, the groove GR may have a closed curve shape around (e.g., surrounding) the intermediate layer LL in a plan view. For example, the groove GR may have a quadrangular ring shape around (e.g., surrounding) the intermediate layer LL in a plan view.

As the example shown in FIG. 16, the cover layer CVL may include the first sub-cover layer SBL1 and the second sub-cover layer SBL2.

Because the first sub-cover layer SBL1 of FIG. 16 is the same as the aforementioned first sub-cover layer SBL1 of FIG. 7, the description of the first sub-cover layer SBL1 of FIG. 16 is substituted with the description of the first sub-cover layer SBL1 of FIG. 7.

The second sub-cover layer SBL2 of FIG. 16 may extend from the first sub-cover layer SBL1. For example, the second sub-cover layer SBL2 may extend from the side surface of the first sub-cover layer SBL1 in the third reverse direction. In other words, the second sub-cover layer SBL2 may extend in a direction perpendicular to the extension direction of the first sub-cover layer SBL1. The second sub-cover layer SBL2 of FIG. 16 may be disposed on the side surface of the intermediate layer LL and the top surface of the semiconductor substrate SSUB (e.g., the top surface of the edge of the semiconductor substrate SSUB). In this case, a part of the second sub-cover layer SBL2 may be disposed in the groove GR of the semiconductor substrate SSUB. According to one or more embodiments, the part of the second sub-cover layer SBL2 may have the same cross-sectional shape as the groove GR. For example, the part of the second sub-cover layer SBL2 disposed in the groove GR may have a triangular cross-sectional shape.

According to one or more embodiments, the second sub-cover layer SBL2 of FIG. 16 may have a diagonally inclined surface S. For example, the second sub-cover layer SBL2 may have the inclined surface S at one end, and the inclined surface S may be disposed on the side surface of the semiconductor substrate SSUB. The inclined surface S may allow the second sub-cover layer SBL2 to have an angle smaller than 90 degrees at the portion overlapping the side surface of the semiconductor substrate SSUB. For example, at one end of the second sub-cover layer SBL2 that overlaps the side surface of the semiconductor substrate SSUB, the interior angle of the second sub-cover layer SBL2 may be an acute angle. According to one or more embodiments, at least a part of the inclined surface S of the second sub-cover layer SBL2 may have a carbonized region.

According to the display device of one or more embodiments shown in FIG. 16, because the cover layer CVL is disposed in the groove GR, the contact area between the cover layer CVL and the substrate SSUB may be further increased. Accordingly, the interferential peeling phenomenon between the cover layer CVL and the substrate SSUB may be further reduced or minimized, and the permeation path of external air and moisture may be more effectively blocked.

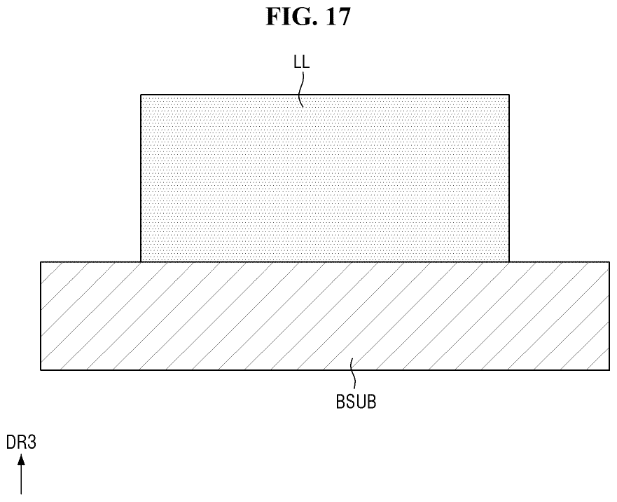

FIGS. 17-23 are process cross-sectional views illustrating a method for fabricating a display device according to one or more embodiments. For example, FIGS. 17-23 may be process cross-sectional views for describing the method for fabricating the aforementioned display device of FIG. 16.

First, as shown in FIG. 17, the intermediate layer LL may be disposed on a mother substrate including the base substrate BSUB (e.g., the semiconductor substrate SSUB). Here, as described above, the base substrate BSUB may include the well region WA, the source region SA, the drain region DA, the channel region CH, the first low-concentration impurity region LDD1, and the second low-concentration impurity region LDD2. According to one or more embodiments, the aforementioned mother substrate may include a wafer.

The intermediate layer LL may include the first semiconductor insulating layer SINS1, the second semiconductor insulating layer SINS2, the third semiconductor insulating layer SINS3, the lower insulating layer BINS, the side insulating layer SINS, the gate electrode GE, the plurality of contact terminals CTE, the light emitting element backplane EBP, the display element layer EML, the encapsulation layer TFE, the organic layer APL, the optical layer OPL, and the filling layer FIL described above.

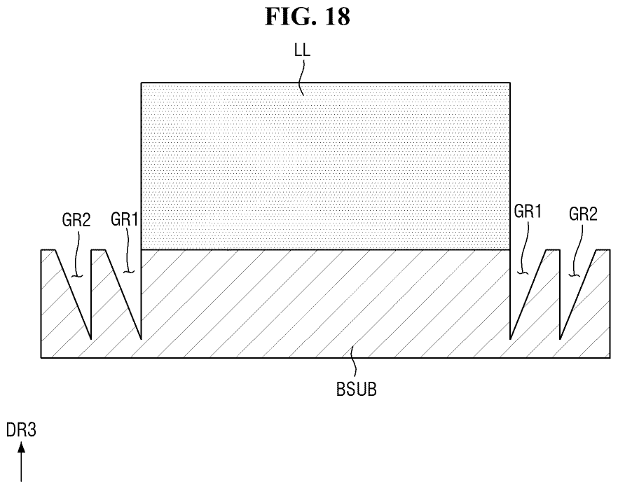

As shown in FIG. 18, a first groove GR1 and a second groove GR2 may be formed at the edges of the base substrate BSUB. Each of the first groove GR1 and the second groove GR2 may be formed in the base substrate BSUB in a recessed shape in the third reverse direction.

The first groove GR1 may have a triangular cross section as illustrated in FIG. 18. For example, the first groove GR1 may have a triangular cross section having a width that gradually decreases along the third reverse direction. According to one or more embodiments, the first groove GR1 may have a closed curve shape around (e.g., surrounding) the intermediate layer LL in a plan view. For example, the first groove GR1 may have a quadrangular ring shape around (e.g., surrounding) the intermediate layer LL in a plan view.

The second groove GR2 may have a triangular cross section as illustrated in FIG. 18. For example, the second groove GR2 may have a triangular cross section having a width that gradually decreases along the third reverse direction. According to one or more embodiments, the second groove GR2 may have a closed curve shape around (e.g., surrounding) the intermediate layer LL and the first groove GR1 in a plan view. For example, the second groove GR2 may have a quadrangular ring shape around (e.g., surrounding) the intermediate layer LL and the first groove GR1 in a plan view. In one or more embodiments, the first groove GR1 may be disposed between the second groove GR2 and the intermediate layer LL in a plan view.

According to one or more embodiments, the second groove GR2 may have a larger length than that of the first groove GR1 in a plan view. Here, the length of the first groove GR1 may be the sum of the size (e.g., the length) of the first groove GR1 in the first direction DR1 and the size (e.g., the length) of the first groove GR1 in the second direction DR2 in a plan view. Similarly, the length of the second groove GR2 may be the sum of the size (e.g., the length) of the second groove GR2 in the first direction DR1 and the size (e.g., the length) of the second groove GR2 in the second direction DR2 in a plan view.

The first groove GR1 and the second groove GR2 may be formed by partially removing the base substrate BSUB. For example, the first groove GR1 and the second groove GR2 may each be formed through an etching process on the base substrate BSUB. For example, the aforementioned first groove GR1 and second groove GR2 may be formed by selectively etching the edges of the base substrate BSUB using an etchant and/or an etching gas.

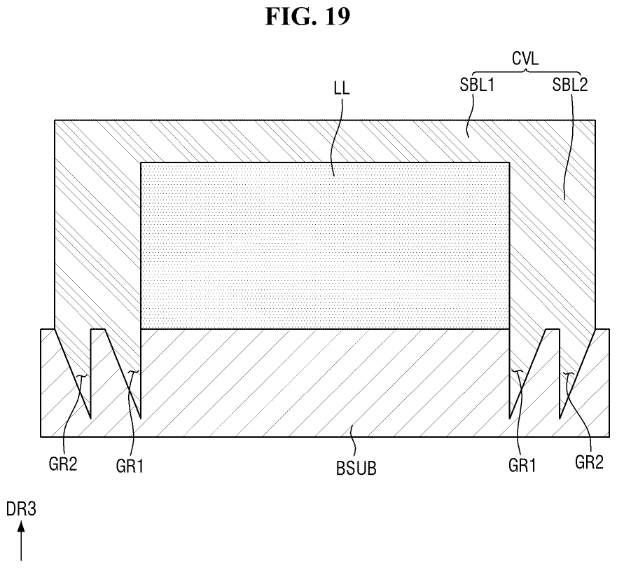

Thereafter, as shown in FIG. 19, the cover layer CVL may be formed on the intermediate layer LL and the base substrate BSUB. In this case, the cover layer CVL may be disposed on the top surface of the intermediate layer LL and the side surface of the intermediate layer LL. In addition, the cover layer CVL may be partially disposed in the first groove GR1 and the second groove GR2 of the base substrate BSUB. For example, the first sub-cover layer SBL1 of the cover layer CVL may be disposed on the intermediate layer LL, the second sub-cover layer SBL2 of the cover layer CVL may be disposed on the side surface of the intermediate layer LL, and portions of the second sub-cover layer SBL2 of the cover layer CVL may be disposed in the first groove GR1 and the second groove GR2 of the base substrate BSUB. According to one or more embodiments, the portions of the second sub-cover layer SBL2 may have the same cross-sectional shape as the first groove GR1 and the second groove GR2. For example, the portions of the second sub-cover layer SBL2 disposed in the first groove GR1 and the second groove GR2 may have a triangular cross section.

According to one or more embodiments, the cover layer CVL may be patterned through a patterning process to be disposed on the top surface of the intermediate layer LL and the side surface of the intermediate layer LL, and in the first groove GR1 and the second groove GR2 of the base substrate BSUB as illustrated in FIG. 19. The aforementioned patterning process may include, for example, a photolithography process and/or an etching process. As a specific example, a polymer resin may be applied (or coated) on the filling layer FIL of the intermediate layer LL and the base substrate BSUB to form a polymer resin layer, and the polymer resin layer may be patterned through a photolithography process and an etching process as described above, thereby forming the cover layer CVL.

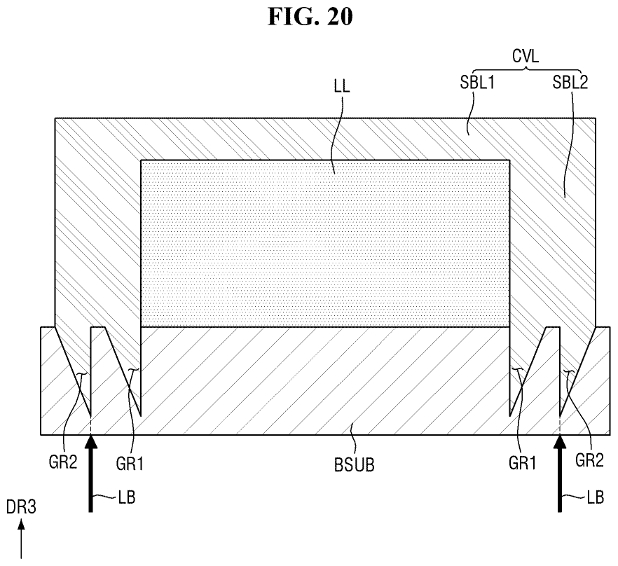

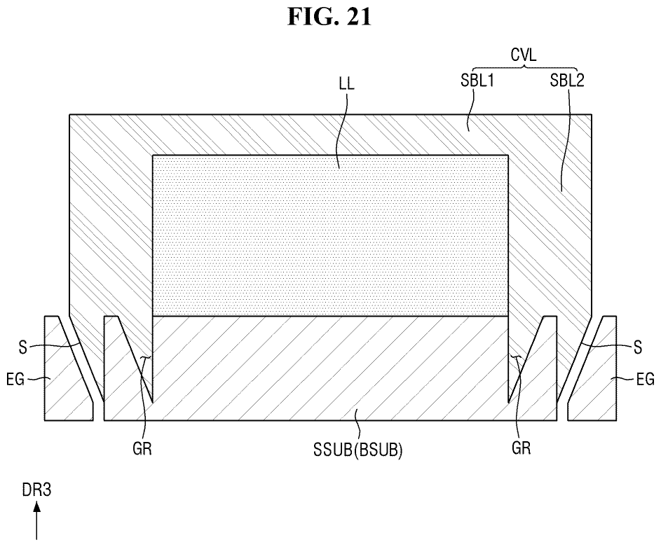

Subsequently, as shown in FIGS. 20 and 21, a process of removing a part of the base substrate BSUB may be performed. For example, the process of removing a part of the base substrate BSUB may include a scribing process of cutting the base substrate BSUB into cells (or wafer chips).

The aforementioned cutting process of the base substrate BSUB may be performed, for example, by a laser cutting process. For example, as shown in FIG. 20, the laser beam LB may be irradiated from below the base substrate BSUB toward the second groove GR2 of the base substrate BSUB in the third direction DR3. According to one or more embodiments, the laser beam LB may be irradiated toward the vertex of the triangular second groove GR2. For example, the laser beam LB may be irradiated toward the vertex of the second groove GR2 disposed at the outermost part of the plurality of grooves GR1 and GR2 (or having a maximum length in a plan view). In this case, the laser beam LB may be irradiated toward a portion of the second groove GR2 (e.g., the vertex of the second groove GR2) located at the lowest portion of the base substrate BSUB. Then, the laser beam LB may penetrate the base substrate BSUB and reach the vertex of the second groove GR2. In this case, the laser beam LB may be irradiated to the cover layer CVL (e.g., the end of the second sub-cover layer SBL2) disposed in the second groove GR2. Accordingly, the end of the second sub-cover layer SBL2 may be at least partially carbonized. The carbonized region may have a black color, for example.

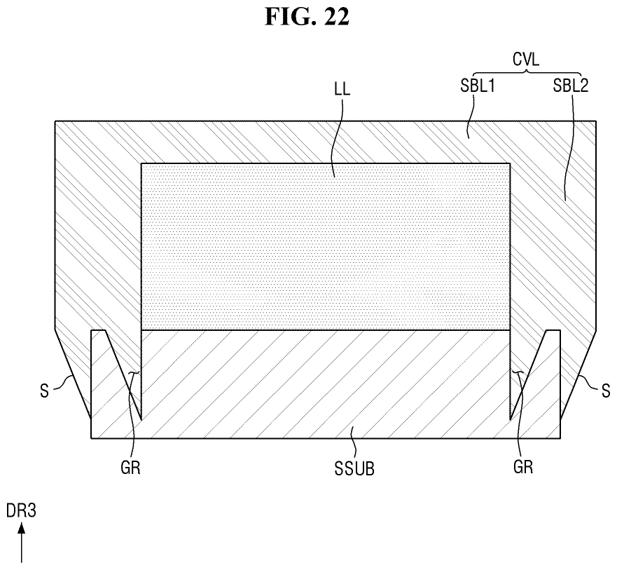

When the aforementioned laser cutting process is completed, both edge portions EG of the base substrate BSUB may be removed as shown in FIG. 21. For example, the edge portion EG of the base substrate BSUB disposed on the outside of the region, to which the laser beam LB is irradiated, may be removed. In this case, because the adhesive force between the inclined surface S of the cover layer CVL and the inclined surface of the edge portion EG facing the inclined surface S is small, when the portion of the base substrate BSUB corresponding to the vertex of the aforementioned second groove GR2 is removed by irradiation of the laser beam LB, the edge portion EG of the base substrate BSUB may be easily removed from the main body of the base substrate BSUB. Therefore, the edge portion EG of the base substrate BSUB is removed by the laser cutting process of FIGS. 20 and 21, thereby forming a substrate of a single cell unit (e.g., the semiconductor substrate SSUB). Then, as shown in FIG. 22, the cover layer CVL disposed on the top surface of the intermediate layer LL, the side surface of the intermediate layer LL, and the side surface of the semiconductor substrate SSUB may be formed.

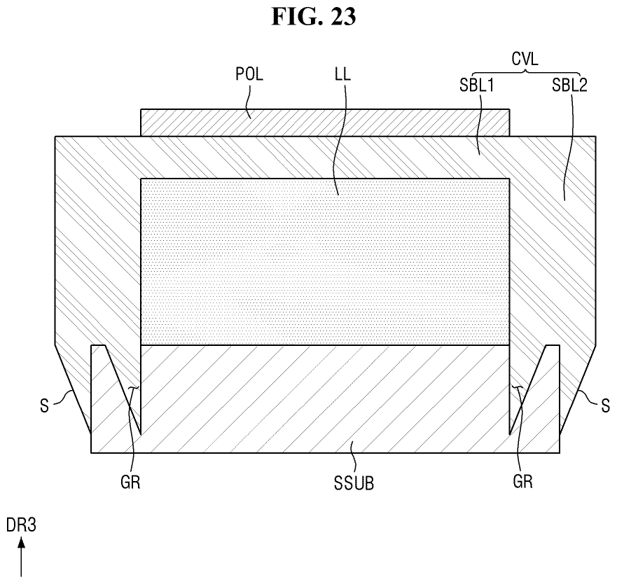

Thereafter, as shown in FIG. 23, the polarizing plate POL may be disposed on the top surface of the cover layer CVL, above the intermediate layer LL. For example, the polarizing plate POL may be disposed on the first sub-cover layer SBL1 of the cover layer CVL.

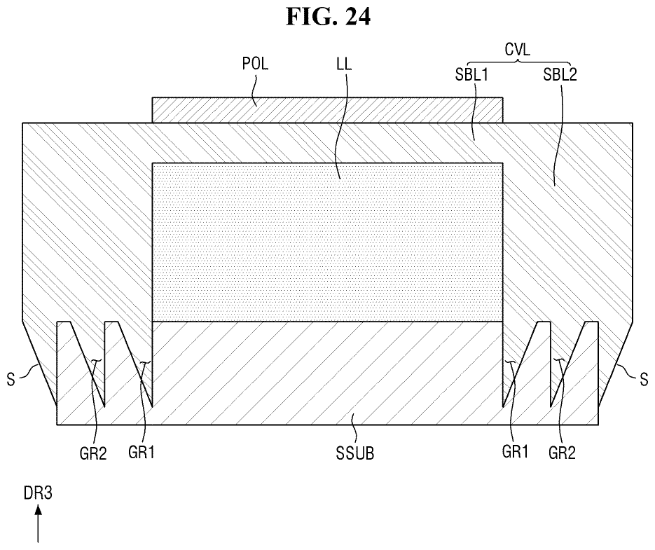

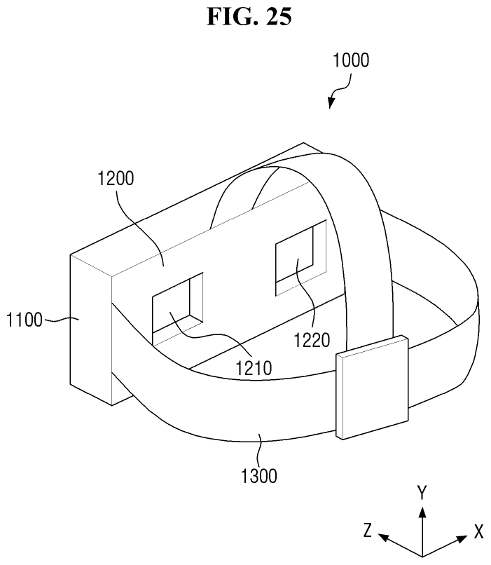

FIG. 24 is a cross-sectional view of a display device according to one or more embodiments.

The display device of FIG. 24 is different from the aforementioned display device of FIG. 16 or FIG. 23 in the shape of the semiconductor substrate SSUB and the shape of the cover layer CVL. The following description will be directed to the difference.

As shown in FIG. 24, the semiconductor substrate SSUB may have at least one groove GR1 and GR2. For example, as shown in FIG. 24, the first groove GR1 and the second groove GR2 may be formed at the edge of the semiconductor substrate SSUB. Each of the first groove GR1 and the second groove GR2 may be formed in the semiconductor substrate SSUB in a recessed shape in the third reverse direction.

The first groove GR1 may have a triangular cross section as illustrated in FIG. 24. For example, the first groove GR1 may have a triangular cross section having a width that gradually decreases along the third reverse direction. According to one or more embodiments, the first groove GR1 may have a closed curve shape around (e.g., surrounding) the intermediate layer LL in a plan view. For example, the first groove GR1 may have a quadrangular ring shape around (e.g., surrounding) the intermediate layer LL in a plan view.

The second groove GR2 may have a triangular cross section as illustrated in FIG. 24. For example, the second groove GR2 may have a triangular cross section having a width that gradually decreases along the third reverse direction. According to one or more embodiments, the second groove GR2 may have a closed curve shape around (e.g., surrounding) the intermediate layer LL and the first groove GR1 in a plan view. For example, the second groove GR2 may have a quadrangular ring shape around (e.g., surrounding) the intermediate layer LL and the first groove GR1 in a plan view. In one or more embodiments, the first groove GR1 may be disposed between the second groove GR2 and the intermediate layer LL in a plan view.

According to one or more embodiments, the second groove GR2 may have a larger length than that of the first groove GR1 in a plan view. Here, the length of the first groove GR1 may be the sum of the size (e.g., the length) of the first groove GR1 in the first direction DR1 and the size (e.g., the length) of the first groove GR1 in the second direction DR2 in a plan view. Similarly, the length of the second groove GR2 may be the sum of the size (e.g., the length) of the second groove GR2 in the first direction DR1 and the size (e.g., the length) of the second groove GR2 in the second direction DR2 in a plan view.

As the example shown in FIG. 24, the cover layer CVL may include the first sub-cover layer SBL1 and the second sub-cover layer SBL2.

Because the first sub-cover layer SBL1 of FIG. 24 is the same as the aforementioned first sub-cover layer SBL1 of FIG. 7, the description of the first sub-cover layer SBL1 of FIG. 24 is substituted with the description of the first sub-cover layer SBL1 of FIG. 7.

The second sub-cover layer SBL2 of FIG. 24 may extend from the first sub-cover layer SBL1. For example, the second sub-cover layer SBL2 may extend from the side surface of the first sub-cover layer SBL1 in the third reverse direction. In other words, the second sub-cover layer SBL2 may extend in a direction perpendicular to the extension direction of the first sub-cover layer SBL1. The second sub-cover layer SBL2 of FIG. 24 may be disposed on the side surface of the intermediate layer LL and the top surface of the semiconductor substrate SSUB (e.g., the top surface of the edge of the semiconductor substrate SSUB). In this case, the second sub-cover layer SBL2 may be partially disposed in the first groove GR1 and the second groove GR2 of the semiconductor substrate SSUB. According to one or more embodiments, the portions of the second sub-cover layer SBL2 may have the same cross-sectional shape as the first groove GR1 and the second groove GR2. For example, the portions of the second sub-cover layer SBL2 disposed in the first groove GR1 and the second groove GR2 may have a triangular cross section.

According to one or more embodiments, the second sub-cover layer SBL2 of FIG. 24 may have a diagonally inclined surface S. For example, the second sub-cover layer SBL2 may have the inclined surface S at one end, and the inclined surface S may be disposed on the side surface of the semiconductor substrate SSUB. The inclined surface S may allow the second sub-cover layer SBL2 to have an angle smaller than 90 degrees at the portion overlapping the side surface of the semiconductor substrate SSUB. For example, at one end of the second sub-cover layer SBL2 that overlaps the side surface of the semiconductor substrate SSUB, the interior angle of the second sub-cover layer SBL2 may be an acute angle. According to one or more embodiments, at least a part of the inclined surface S of the second sub-cover layer SBL2 may have a carbonized region.

As such, the display device according to one or more embodiments may include at least one groove GR1 and GR2.

According to one or more embodiments, when the display device has the plurality of grooves GR1 and GR2, the plurality of grooves GR1 and GR2 may have a larger length as they are closer to the side surface (or the periphery) of the substrate (e.g., the semiconductor substrate SSUB).

According to one or more embodiments, in the display device of FIG. 24, because the cover layer CVL is disposed in the groove GR, the contact area between the cover layer CVL and the substrate SSUB may be further increased. Accordingly, the interferential peeling phenomenon between the cover layer CVL and the substrate SSUB may be further reduced or minimized, and the permeation path of external air and moisture may be more effectively blocked.

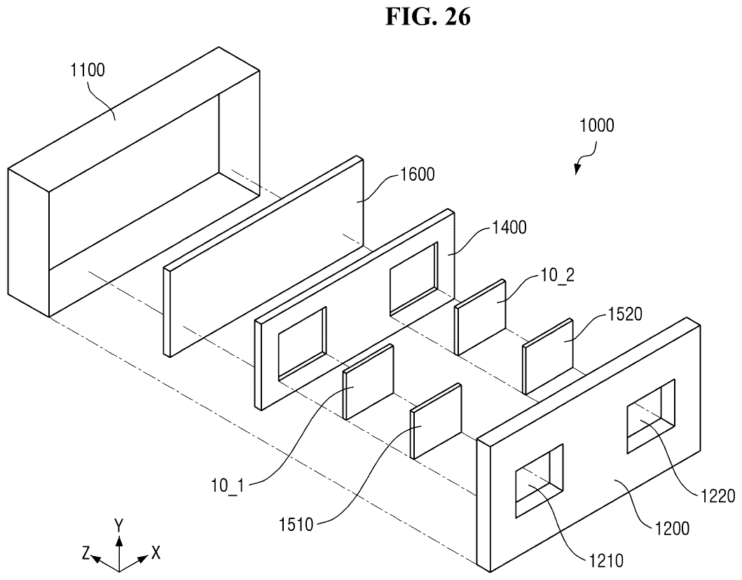

FIG. 25 is a perspective view illustrating a head mounted display according to one or more embodiments. FIG. 26 is an exploded perspective view illustrating an example of the head mounted display of FIG. 25.

Referring to FIGS. 25 and 26, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1-8, the description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 25 and 26 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

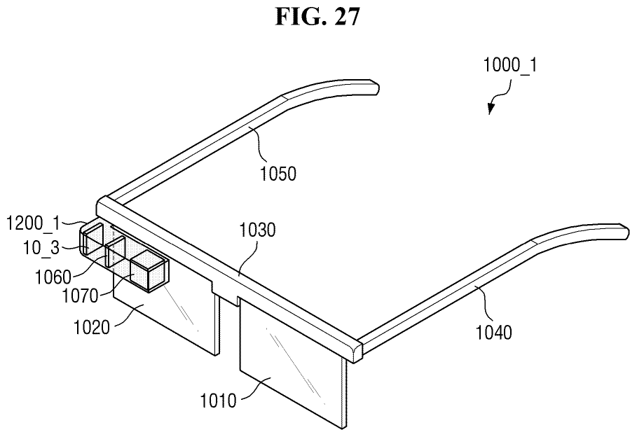

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1200 is implemented to be lightweight and compact, the head mounted display 1000 may be provided with, as shown in FIG. 27, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, and/or a high-definition multimedia interface (HDMI) terminal, and the wireless communication module may be a 5G communication module, a 4G communication module, a Wi-Fi module, and/or a Bluetooth module.

FIG. 27 is a perspective view illustrating a head mounted display according to one or more embodiments.

Referring to FIG. 27, a head mounted display 1000_1 according to one or more embodiments may be an eyeglasses-type display device in which a display device housing 1200_1 is implemented in a lightweight and compact manner. The head mounted display 1000_1 according to one or more embodiments may include a display device 103, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 27 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate;
an intermediate layer on the substrate, and comprising a first electrode, a light emitting layer on the first electrode, a second electrode on the light emitting layer, and a filling layer on the second electrode; and
a cover layer on the intermediate layer,
wherein the cover layer is on a top surface of the intermediate layer, a side surface of the intermediate layer, and a side surface of the substrate.

2. The display device of claim 1, wherein the cover layer is on the filling layer.

3. The display device of claim 1, wherein the cover layer comprises:
a first sub-cover layer on the intermediate layer; and
a second sub-cover layer extending from the first sub-cover layer and on the side surface of the intermediate layer and the side surface of the substrate.

4. The display device of claim 3, wherein the first sub-cover layer is on the intermediate layer, and
wherein the second sub-cover layer is around the side surface of the intermediate layer and the side surface of the substrate.

5. The display device of claim 3, wherein the second sub-cover layer has a diagonally inclined surface at one end.

6. The display device of claim 5, wherein the inclined surface of the second sub-cover layer is on the side surface of the substrate.

7. The display device of claim 3, wherein one end of the second sub-cover layer has a carbonized region.

8. The display device of claim 1, wherein the cover layer is around the side surface of the intermediate layer and the side surface of the substrate.

9. The display device of claim 1, wherein the intermediate layer is surrounded by the cover layer and the substrate.

10. The display device of claim 1, wherein the substrate has a groove at an edge.

11. The display device of claim 10, wherein in a plan view, the groove is around the intermediate layer.

12. The display device of claim 10, wherein the groove has a triangular cross section.

13. The display device of claim 10, wherein a part of the cover layer is in the groove.

14. The display device of claim 10, wherein the groove comprises a plurality of grooves, and
wherein respective lengths of the plurality of grooves increase as the grooves are positioned closer to the side surface of the substrate.

15. The display device of claim 14, wherein a part of the cover layer is in each of the plurality of grooves.

16. The display device of claim 1, further comprising a polarizing plate on the intermediate layer.

17. A display device comprising:
a substrate;
an intermediate layer on the substrate; and
a cover layer on the intermediate layer,
wherein the intermediate layer comprises a light emitting layer, and
wherein the cover layer is on a top surface of the intermediate layer, a side surface of the intermediate layer, and a side surface of the substrate.

18. The display device of claim 17, wherein the cover layer is around the side surface of the intermediate layer and the side surface of the substrate.

19. The display device of claim 17, wherein the intermediate layer is surrounded by the cover layer and the substrate.

20. The display device of claim 17, wherein the substrate has a groove at an edge.

21. The display device of claim 20, wherein in a plan view, the groove is around the intermediate layer.

22. The display device of claim 20, wherein the groove has a triangular cross section.

23. The display device of claim 20, wherein a part of the cover layer is in the groove.

24. A method for fabricating a display device comprising:
forming an intermediate layer comprising a light emitting layer, on a base substrate;
forming a groove at an edge of the base substrate;
forming a cover layer which is inserted into the groove of the base substrate, and on a top surface of the intermediate layer and a side surface of the intermediate layer; and
removing an edge portion of the base substrate based on the groove to form a substrate,
wherein after the removing of the edge portion of the base substrate, the cover layer is formed on the top surface of the intermediate layer, the side surface of the intermediate layer, and a side surface of the substrate.

25. The method of claim 24, wherein the forming of the groove at the edge of the base substrate comprises etching an edge of a top surface of the base substrate.

26. The method of claim 24, wherein the removing of the edge portion of the base substrate based on the groove to form the substrate comprises irradiating a laser beam from below the base substrate toward the groove.
